(19) United States
(12) Patent Application Publication
(10) Pub. No.: US 2023/0209713 A1
(43) Pub. Date: Jun. 29, 2023

(54) PAD ARRANGING METHOD AND PAD ARRANGEMENT STRUCTURE

(71) Applicant: KINPO ELECTRONICS, INC., New Taipei City (TW)

(72) Inventors: Chuan-Wang CHANG, NEW TAIPEI CITY (TW); Yu-Ta LIN, NEW TAIPEI CITY (TW); Chen-Jung CHEN, NEW TAIPEI CITY (TW)

(21) Appl. No.: 17/672,330

(22) Filed: Feb. 15, 2022

(30) Foreign Application Priority Data
Dec. 24, 2021 (CN) 202111601713.X

(51) Int. Cl. H05K 1/11; H01L 23/49; H01L 23/00

(52) U.S. Cl. CPC H05K 1/119; H01L 23/49; H01L 24/49; H01L 2224/48227; H01L 24/48; H01L 2224/49173; H05K 2201/09027; H05K 2201/09409; H05K 2201/09418; H05K 2201/0939; H05K 2201/094

(57) ABSTRACT

A pad arranging method and a pad arrangement structure for a wire bonding of a chip is provided. The method includes following steps. A soldered component and a circuit board are provided. A plurality of pads is arranged on the circuit board. a number of the pads is corresponding to a number of a plurality pins of the soldered component. The pads are disposed in a plurality of rows toward or away from the soldered component according to a predetermined arranging position, and the number of the pads on one of the rows at outer side is equal to that on one of the rows at inner side, or greater than that on one of the rows at inner side by one or more than one

### BACKGROUND OF THE DISCLOSURE

### Technical Field

This disclosure is directed to a packaging art of an integrated circuit, and in particular to a pad arranging method and a pad arrangement structure for a wire bonding of a chip.

### Description of Related Art

According to a related art of semiconductor packaging, in a packaging technology such as chip on board (COB), the die is provided and the circuit layouts are further disposed via the aforementioned COB process to accomplish the function thereof. A related art COB process can effectively reduce cost of manufacturing and is therefore widely applied.

However, functions of the dies are gradually increased and enhanced with the developing technology, so that a number of pins on the die for soldering is correspondingly increased. Therefore, defect rates are increased with an increasing difficulty of a wire bonding step in the COB process.

According to a schematic view of FIG. 1 showing a related art wire bonding process of a die, the die 1 is arranged on a circuit board 2, and the required pads (such as A1 to A56 and B1 to B32 shown in this figure; besides A2 to A55 and B2 to B21 are not labeled for simplicity) for the dies 1 are arranged on the circuit board 2. The number of the required pads should be disposed according to a number of the pins of the die 1, and the pads need to be kept in certain distances to avoid conduction. The pins of the die 1 are generally arranged on an edge of the die 1 such as a long edge “a” or a short edge “b”. In the aforementioned status, an arrangement of the pads should be extended outward with respect to the number of the pads increased with the increased number of the pins on the die 1, so that the wire bonding process becomes more difficult and the yield is affected.

According to an example shown in FIG. 1, an angle θa is defined between a linear wire bonding line and each of the bonding wires (AS1 and AS56) of the die 1 with the pads (A1 and A56) at two outermost sides. Once the pin number on the long edge “a” of the die 1 are increased, the arrangement of the pads at two ends needs to be outward extended accordingly, so that the angle θa is correspondingly widened. In the same way, regarding the short edge “b” of the die 1, an angle θb is defined at each of the bonding wires (BS1 and BS32) of the die 1 with the pads (B1 and B32) at two outmost sides and this also occurs the aforementioned problem.

In view of the above drawbacks, the inventor proposes this disclosure based on his expert knowledge and elaborate researches in order to solve the problems of related art.

### SUMMARY OF THE DISCLOSURE

This disclosure is directed to a pad arranging method and a pad arrangement structure for a wire bonding of a chip, which may reduce an angle and a length of a wire bonding. Therefore, spaces on the circuit board may be arranged more efficiently and the wire bonding length may be shortened to improve a performance of the wire bonding operation in COB process.

One of the exemplary embodiments, the pad arranging method for the wire bonding of the wire is provided, the method has following steps:

a) providing a soldered component and a circuit board for the soldered component to be disposed; and

b) arranging a plurality of pads on the circuit board, a number of the pads being corresponding to a pin number of the soldered component;

wherein the pads are disposed in a plurality of rows toward or away from the soldered component according to a predetermined arranging position, and the number of the pads on one of the rows at outer side is equal to that on one of the rows at inner side, or greater than that on one of the rows at inner side by one or more than one.

Another one of the exemplary embodiments, the pad arrangement structure for the wire bonding of the chip is provided, the structure including: a soldered component including a plurality of pins; and a circuit board, the soldered component disposed thereon, and including a plurality of pads. A number of the pads is corresponding to a number of the pins of the soldered component. The pads are disposed in a plurality of rows toward or away from the soldered component according to a predetermined arranging position, and the number of the pads on one of the rows at outer side is equal to that on one of the rows at inner side, or greater than that on one of the rows at inner side by one or more than one.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a schematic view showing related pads for wire bonding of chip.

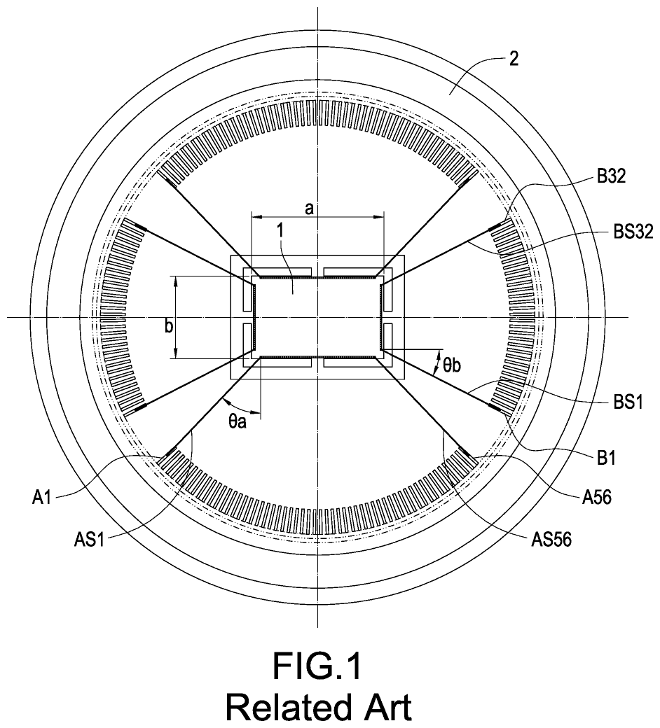

FIG. 2 is a schematic view showing an embodiment of this disclosure.

FIG. 3 is a partially enlarged view showing a portion “A” in FIG. 2.

FIG. 4 is a partially enlarged view showing a portion “B” in FIG. 2.

FIG. 5 is a schematic view showing another embodiment of this disclosure.

FIG. 6 is a schematic view showing an embodiment of the pad according to this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

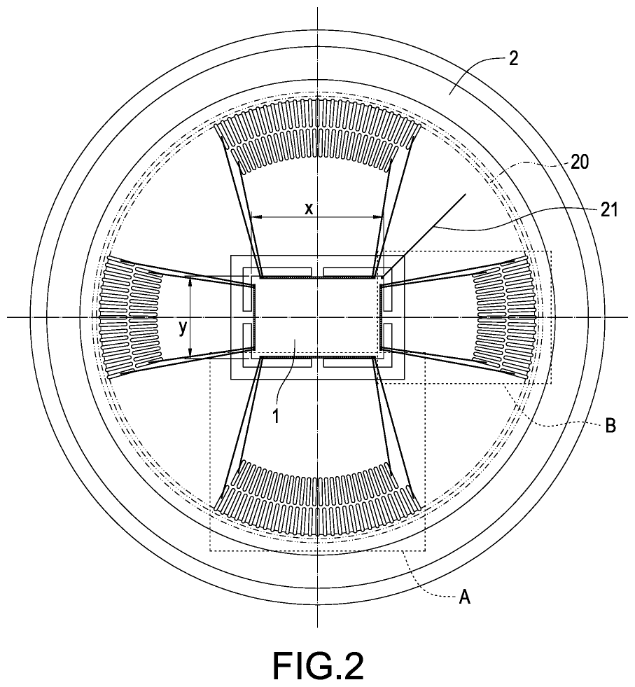

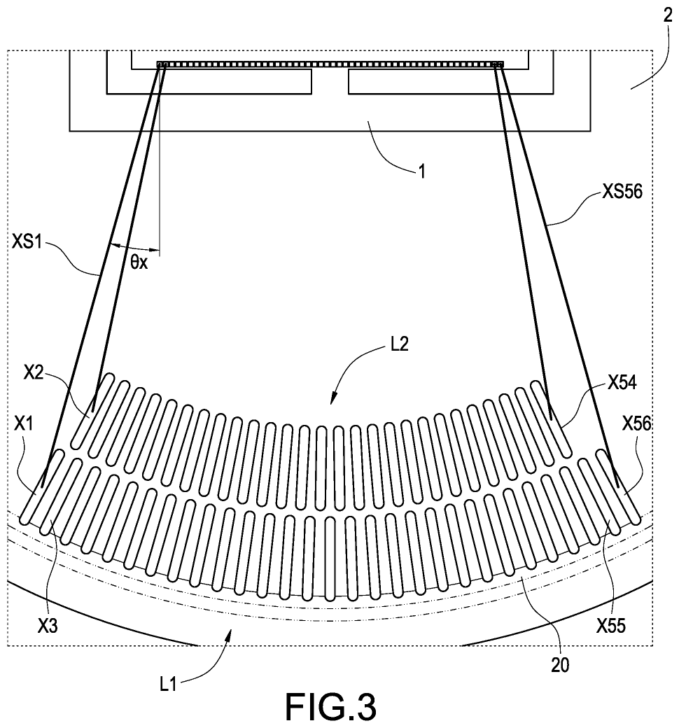

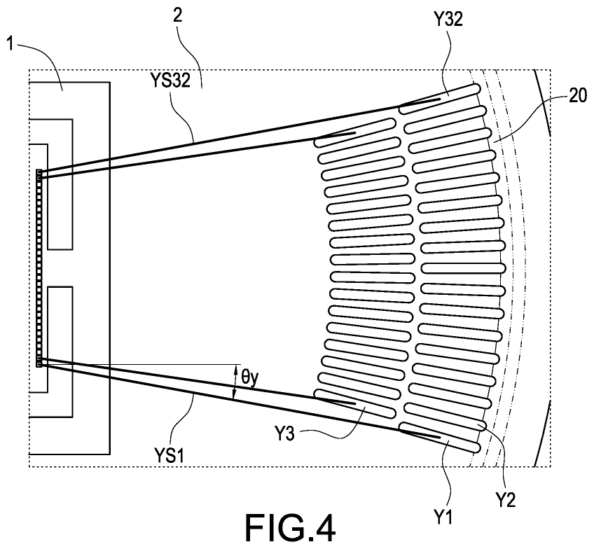

Please refer to FIG. 2 which is a schematic view showing an embodiment of this disclosure. This disclosure is directed to a pad arranging method and a pad arrangement structure for a wire bonding of a chip. A soldered component 1 and a circuit board 2 for the soldered component 1 to be disposed thereon are provided. The soldered component 1 may be a die or a packaged semiconductor component, and a plurality of pads are arranged on the circuit board 2. The number of the pads is corresponding to a number of a plurality pins of the soldered component 1. For example, the soldered component 1 of this disclosure has two first edges “x” and two second edges “y”, fifty six (56) pins are provided on each first edge “x” of the soldered component 1 and those are corresponding to the pads X1 to X56 (as shown in FIG. 3, while X4 to X53 are not labeled for simplicity), thirty two (32) pins are provided at each second edge “y” and those are corresponding to the pads Y1 to Y32 (as shown in FIG. 4, while Y4 to Y31 are not labeled for simplicity), and it should be noted that the aforementioned number of the pads is not limited.

Please refer to the example in FIGS. 2 and 3 that the first edge “x” of the aforementioned soldered component 1 is disposed corresponding to the pads X1 to X56 of the circuit board 2, the required pads X1 to X56 are arranged on the circuit board 2 according to a predetermined arranging position 20 (such as an arrangement standard of a concentric-circle arrangement defined on the circuit board or other configurations that may be used for design), in a manner of arranging to a plurality of rows L1/L2 in a direction toward the soldered component 1, or a direction away from the soldered component 1, and the number of the pads in the row L1 disposed relatively outside is equal to that in the row L2 disposed relatively inside, or greater than in the row L2 disposed relatively inside by one more than one. In some embodiments, the pads in the respective rows L1/L2 are arranged staggeredly from each other, namely any pad in the row L2 is aligned to the interval of any two pads in row L1. Specifically, according to this embodiment, “fifty-six” pins are provided at the first edge “x” of the soldered component 1, and “fifty-six” pads X1 to X56 need to be correspondingly disposed on the circuit board 2. Accordingly, the pads (X1, X3 . . . and X55) of odd number in the pads (X1 to X56) may be disposed in the row L1, the pads (X2, X4 . . . and X54) of even number in the pads (X1 to X56) may be disposed in the row L2, the row L1 of odd number is disposed at outside of the row L2 of even number, and the residual pad X56 may be disposed in the outer row L1 or the inner row L2 (in the embodiment, it is disposed at the outer row L1, and the outer row L1 has additional two pads more than the inner row L2, and in the condition of “more than”, the number difference between the outer row L1 and the inner row L2 is generally not more than two).

Accordingly, the aforementioned arranging method may relatively inward decrease an angle θx between the wires (XS1 and XS56) bonded to the pads (X1/X56) at two outermost sides of the row L1 (because the number of the pads in each row is decreased about half). An angle between the pads (X2/X54) at two outermost sides of the inner row L2 may not be greater than the aforementioned angle θx, because the number of pads in the inner row L2 is equal to the number of the outer row L1 at most, and the wire bonding to the row L2 may be shortened significantly. Accordingly, this disclosure may achieve an effect of optimizing the aforementioned angle θx of wire bonding and shortening the wires through the aforementioned method, and the yield rate in the COB process may be further improved, and the cost of material waste and rework caused by the defect rate may be reduced so as to reduce material cost in production.

Furthermore, please refer to both of FIGS. 2 and 4, here uses the second edge “y” of the aforementioned soldered component 1 corresponding to the pads (Y1 to Y32) of the circuit board 2 as an example. The pads (Y1 to Y32) are arranged on the circuit board 2 according to the predetermined arranging position 20 slimier to the aforementioned arrangement, based on a number of the pins on the second edge “y” of the soldered component 1. It should be noted that an angle θy between the wires YS1 and YS32 may also be relatively inward decreased.

Therefore, the pad arranging method and pad arrangement structure for the wire bonding of the chip is this disclosure may be achieved by the aforementioned configuration.

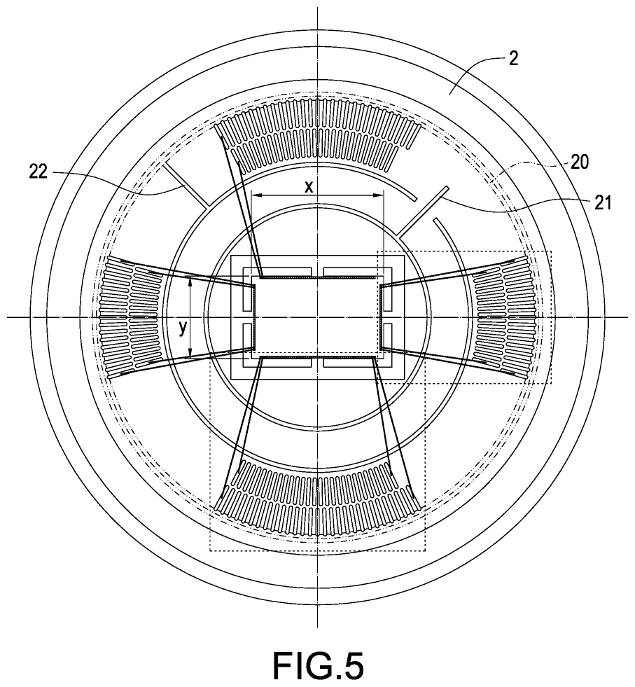

Accordingly, the angles θx and θy in the wire boding may be effectively reduced by the aforementioned pad arranging method and pad arrangement structure according to this disclosure, and the length of the wire boding may also be shortened. Therefore, a performance of the wire bonding operation in COB process may be effectively improved (The shorter the wire, the better the performance). Moreover, the space on the circuit board 2 may be used effectively, and more space on the circuit board 2 may be reserved for other designs. According to FIG. 2, the circuit board 2 has enough space the circuit layout of ground pad/pattern 21 (GND). Alternatively, according to FIG. 5, the ground pad/pattern 21 (GND) or the component voltage (VCC or VDD) pad/pattern may also be respectively laid out outside the predetermined arranging position 20 on the circuit board 2, such as disposed between the soldered component 1 and the pads.

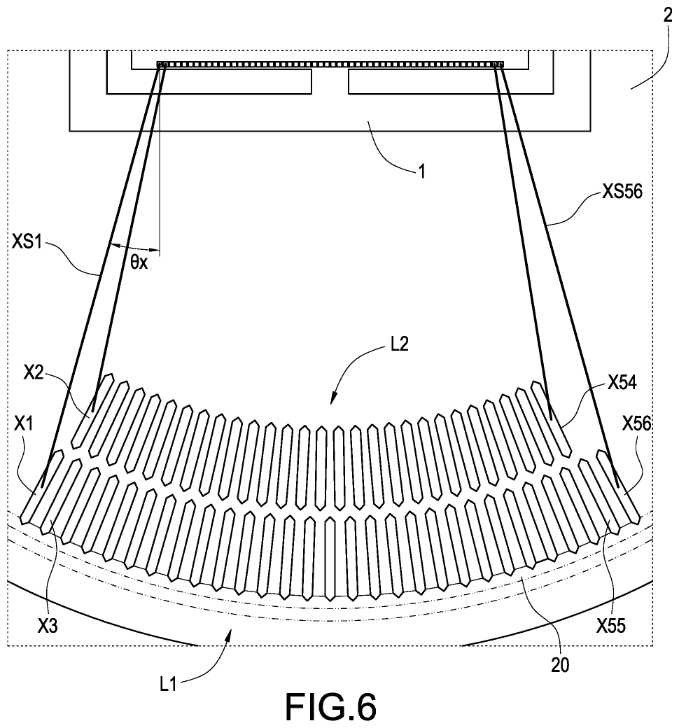

Further referring to FIGS. 3, 4 and 6, according to this disclosure, the shapes of the aforementioned pads (X1 to X56 and Y1 to Y32) are of elongated shapes, and two ends of the elongated shape of each pad may be a curve end as shown in FIGS. 3 and 4 or a sharp end as shown in FIG. 6. According to the embodiment shown in FIG. 6, the pads in the respective rows are arranged staggeredly from each other to make the intervals between the pads in each row be uniform and improve the image recognition of automatic machine or the automatic image recognition.

Accordingly, this disclosure may be applied to achieves the predetermined purpose so as to solves the problems of the related art. While this disclosure has been described by means of specific embodiments, numerous modifications and variations could be made thereto by those skilled in the art without departing from the scope and spirit of this disclosure set forth in the claims.

What is claimed is:

1. A pad arranging method for a wire bonding of a chip, the method comprising:
a) providing a soldered component and a circuit board for the soldered component to be disposed; and
b) arranging a plurality of pads on the circuit board, a number of the pads being corresponding to a pin number of the soldered component;
wherein the pads are disposed in a plurality of rows toward or away from the soldered component according to a predetermined arranging position, and the number of the pads on one of the rows at outer side is equal to that on one of the rows at inner side, or greater than that on one of the rows at inner side by one or more than one.

2. The pad arranging method according to claim 1, wherein the soldered component comprises a die or a packaged semiconductor component.

3. The pad arranging method according to claim 1, further comprising: staggeredly arranging the pads between different rows.

4. The pad arranging method according to claim 1, further comprising: respectively arranging the pads with an odd number and an even number according to a pin sequence.

5. The pad arranging method according to claim 1, further comprising: arranging the pads to the plurality of rows in a direction toward the soldered component or a direction away from the soldered component based on an arrangement standard of a concentric-circle arrangement defined on the circuit board.

6. The pad arranging method according to claim 1, wherein each pad is of an elongated shape.

7. The pad arranging method according to claim 6, wherein two ends of the elongated shape of each pad are a curve end or a sharp end.

8. The pad arranging method according to claim 1, further comprising: laying out a ground pad/pattern or a component voltage pad/pattern outside the predetermined arranging position on the circuit board.

9. The pad arranging method according to claim 8, further comprising: laying out the ground pad/pattern or the component voltage pad/pattern between the soldered component and the pads.

10. A pad arrangement structure for a wire bonding of a chip, the pad arrangement structure comprising:
a soldered component, comprising a plurality of pins; and
a circuit board, the soldered component disposed thereon, and comprising a plurality of pads, wherein a number of the pads is corresponding to a number of the pins of the soldered component,
wherein the pads are disposed in a plurality of rows toward or away from the soldered component according to a predetermined arranging position, and the number of the pads on one of the rows at outer side is equal to that on one of the rows at inner side, or greater than that on one of the rows at inner side by one or more than one.

11. The pad arrangement structure according to claim 10, wherein the soldered component comprises a die or a packaged semiconductor component.

12. The pad arrangement structure according to claim 10, wherein the pads are staggeredly arranged between different rows.

13. The pad arrangement structure according to claim 10, wherein the pads are respectively arranged with an odd number and an even number according to a pin sequence.

14. The pad arrangement structure for chip bonding according to claim 10, wherein the pads are arranged to the plurality of rows in a direction toward the soldered component or a direction away from the soldered component based on an arrangement standard of a concentric-circle arrangement defined on the circuit board.

15. The pad arrangement structure for chip bonding according to claim 10, wherein each pad is of an elongated shape.

16. The pad arrangement structure for chip bonding according to claim 15, wherein two ends of the elongated shape of each pad are a curve end or a sharp end.

17. The pad arrangement structure for chip bonding according to claim 10, wherein a ground pad/pattern or a component voltage pad/pattern is laid out outside the predetermined arranging position on the circuit board.

18. The pad arrangement structure for chip bonding according to claim 17, wherein the ground pad/pattern or the component voltage pad/pattern is laid out between the soldered component and the pads.
